(19) United States
(12) Patent Application Publication
(10) Pub. No.: US 2025/0329687 A1
(43) Pub. Date: Oct. 23, 2025

(54) BONDING APPARATUS AND OPERATING METHOD THEREOF

(71) Applicant: SAMSUNG ELECTRONICS CO., LTD., Suwon-si, Gyeonggi-do (KR)

(72) Inventors: Sun Chul KIM, Suwon-si (KR); Tae Jae PARK, Suwon-si (KR); Chae In MOON, Suwon-si (KR)

(21) Appl. No.: 19/020,876

(22) Filed: Jan. 14, 2025

(30) Foreign Application Priority Data
Apr. 22, 2024 (KR) 10-2024-0053111

(51) Int. Cl. H01L 23/00; H05B 6/02

(52) U.S. Cl. CPC H01L 24/75; H01L 24/81; H05B 6/02; H01L 2224/75264; H01L 2224/75744; H01L 2224/75745; H01L 2224/8118; H01L 2224/81222

(57) ABSTRACT

A bonding apparatus includes a plurality of units each having a first holder configured to support a substrate and a second holder above the first holder that is configured to mount a semiconductor chip on the substrate. The plurality of units are arranged in adjacent spaced apart relationship along a first direction. An induction heating system includes an induction coil and an alternating current supplying unit configured to apply an alternating current to the induction coil so as to heat a junction between a substrate and a semiconductor chip at each of the plurality of units by inducing a magnetic field around the induction coil. A transferring unit is configured to position the induction coil adjacent to each of the plurality of units, and the induction heating system is configured to sequentially heat the junction between a substrate and semiconductor chip at each of the plurality of units.

### CROSS-REFERENCE TO RELATED APPLICATIONS

This application claims priority from Korean Patent Application No. 10-2024-0053111 filed on Apr. 22, 2024 in the Korean Intellectual Property Office, the disclosure of which is incorporated herein by reference in its entirety.

### BACKGROUND

### 1. Technical Field

The present disclosure relates to a bonding apparatus and an operating method thereof, and more particularly, to a bonding apparatus capable of improving the productivity of a semiconductor package manufacturing process and an operating method thereof.

### 2. Description of the Related Art

A process of packaging a semiconductor chip includes an assembly process for providing the semiconductor chip with a solder bump that functions as a terminal for electrical connection to the outside, and a mounting process for mounting the semiconductor chip provided with the solder bump onto a substrate. After each of the assembly process and the mounting process, a process of reflowing the solder bump by applying heat to the solder bump is required.

An example of the process of reflowing the solder bump includes a thermo-compression bonding process, which applies heat and pressure to the substrate and the semiconductor chip mounted thereon to bond the semiconductor chip onto the substrate. In the thermo-compression bonding process, soldering is performed by heat transfer by a conduction method from a heater embedded in a tool that picks up the semiconductor chip and mounts it on the substrate. Since the soldering process based on heat transfer by the conduction method takes a long time for heating and cooling, research on a bonding process that can increase productivity is underway.

### SUMMARY OF THE INVENTION

Aspects of the present disclosure provide a bonding apparatus capable of improving the productivity of a semiconductor package manufacturing process.

Aspects of the present disclosure also provide an operating method of a bonding apparatus capable of improving the productivity of a semiconductor package manufacturing process.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is a provided a bonding apparatus having a plurality of units, each of the plurality of units having a first holder configured to support a substrate and a semiconductor chip with a junction therebetween, and a second holder above the first holder, wherein the second holder is configured to mount the semiconductor chip on the substrate and apply pressure to the semiconductor chip, wherein the plurality of units are arranged in adjacent spaced apart relationship along a first direction, an induction heating system having a first induction coil and a first alternating current supplying unit configured to apply an alternating current to the first induction coil, wherein the induction heating system is configured to heat the junction between the substrate and the semiconductor chip at each of the plurality of units by inducing a magnetic field around the first induction coil. A first transferring unit is connected to the first induction coil, and the first transferring unit is configured to position the first induction coil adjacent each of the plurality of units, wherein the first transferring unit is configured to move the first induction coil along the first direction, and wherein the induction heating system is configured to sequentially heat the respective junctions between the substrate and the semiconductor chip at each of the plurality of units as the first induction coil moves along the first direction.

According to an aspect of the present disclosure, there is a provided a bonding apparatus having a plurality of units, each of the plurality of units having a first holder configured to support a substrate and a semiconductor chip with a junction therebetween, and a second holder spaced apart from the first holder, wherein the second holder is configured to mount the semiconductor chip on the substrate, and wherein the plurality of units are arranged in a circular configuration, an induction heating system having a first induction coil and a first alternating current supplying unit configured to apply an alternating current to the first induction coil, wherein the induction heating system is configured to heat the junction between the substrate and the semiconductor chip at each of the plurality of units by inducing a magnetic field around the first induction coil, and a first transferring unit connected to the first induction coil, wherein the first transferring unit is configured to position the first induction coil adjacent each of the plurality of units, wherein the first transferring unit is configured to move the first induction coil along a circular path and in adjacent spaced apart relationship with the plurality of units, and wherein the induction heating system is configured to sequentially heat the junction between the substrate and the semiconductor chip at each of the plurality of units as the first induction coil is moved along the circular path.

According to an aspect of the present disclosure, there is a provided a method of operating a bonding apparatus including supporting a first substrate with a first holder, picking up a first semiconductor chip with a second holder, and then aligning and mounting the first semiconductor chip on the first substrate using the second holder, positioning, via a first transferring unit, a first induction coil in adjacent spaced apart relationship with the second holder, applying, via a first alternating current supplying unit, an alternating current to the first induction coil to heat a first junction between the first substrate and the first semiconductor chip by inducing a magnetic field around the first induction coil, positioning, via the first transferring unit, the first induction coil in adjacent spaced apart relationship with a second substrate and a second semiconductor chip mounted on the second substrate, wherein the second substrate and the second semiconductor chip are adjacent the first substrate and the first semiconductor chip, and applying, via the first alternating current supplying unit, an alternating current to the first induction coil to heat a second junction between the second substrate and the second semiconductor chip by inducing a magnetic field around the first induction coil.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram for describing a bonding apparatus according to some embodiments.

FIGS. 2 to 4 are diagrams for describing an operating method of the bonding apparatus of FIG. 1.

FIG. 5 is a diagram for describing a bonding apparatus according to some embodiments.

FIG. 6 is a diagram for describing a bonding apparatus according to some embodiments.

FIGS. 7 to 9 are diagrams for describing an operating method of the bonding apparatus of FIG. 6.

FIG. 10 is a diagram for describing a bonding apparatus according to some embodiments.

FIGS. 11 to 15 are diagrams for describing an operating method of the bonding apparatus of FIG. 10.

FIG. 16 is a diagram for describing a bonding apparatus according to some embodiments.

FIG. 17 is a diagram for describing a bonding apparatus according to some embodiments.

FIG. 18 is a diagram for describing a bonding apparatus according to some embodiments.

FIG. 19 is a flowchart illustrating an operating method of a bonding apparatus according to some embodiments.

FIGS. 20 to 28 are diagrams for describing an operating method of a bonding apparatus according to the flowchart of FIG. 19.

### DETAILED DESCRIPTION

Hereinafter, a bonding apparatus and an operating method thereof according to some embodiments will be described with reference to the accompanying drawings.

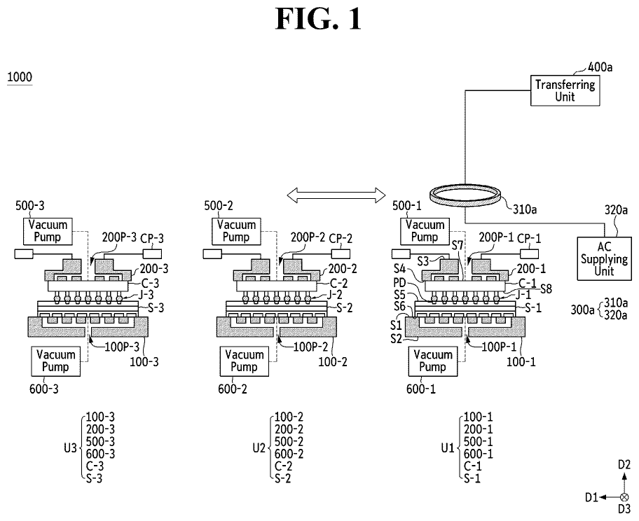

FIG. 1 is a diagram for describing a bonding apparatus according to some embodiments.

Referring to FIG. 1, a bonding apparatus 1000 may include a plurality of units U1, U2, and U3, an induction heating system 300a, and a transferring unit 400a.

The plurality of units U1, U2, and U3 may be arranged side by side in a row along a first direction D1. In FIG. 1, the number of the plurality of units U1, U2, and U3 is shown as three, but this is merely for simplicity of illustration, and the number of the plurality of units U1, U2, and U3 is not limited thereto. The number of the plurality of units U1, U2, and U3 included in the bonding apparatus 1000 may vary depending on the embodiment and may be implemented as four or more.

The unit U1 may include a holder 100-1, a holder 200-1, a vacuum pump 500-1, a vacuum pump 600-1, a semiconductor chip C-1, a substrate S-1, and a junction J-1. The unit U2 may include a holder 100-2, a holder 200-2, a vacuum pump 500-2, a vacuum pump 600-2, a semiconductor chip C-2, a substrate S-2, and a junction J-2. The unit U3 may include a holder 100-3, a holder 200-3, a vacuum pump 500-3, a vacuum pump 600-3, a semiconductor chip C-3, a substrate S-3, and a junction J-3. However, according to the embodiment, each of the units U1, U2, and U3 may further include at least one other component in addition to the listed components.

Each of the units U1, U2, and U3 may include the same components. Accordingly, the description of the units U2 and U3 may be replaced by the description of the unit U1, and thus the description of the units U2 and U3 will be replaced by the description of the unit U1 in the following. In addition, in the following description, a upper surface (or above) is referenced to a second direction D2, and a lower surface (or below) is referenced to the opposite direction of the second direction D2.

The holder 100-1 may be configured to support a semiconductor package configuration. The semiconductor package configuration may include the substrate S-1, the semiconductor chip C-1, and the junction J-1. The holder 100-1 may include a first surface S1 and a second surface S2 that are opposite to each other in the second direction D2. The first surface S1 may be the upper surface of the holder 100-1, and the second surface S2 may be the lower surface of the holder 100-1. The first surface S1 of the holder 100-1 may support the substrate S-1.

The holder 100-1 may include a pipe or passageway 100P-1 therein. The passageway 100P-1 may be installed or formed inside the holder 100-1 and is an empty space extending in the first direction D1 and the second direction D2. The passageway 100P-1 may be connected to the vacuum pump 600-1. The vacuum pump 600-1 may perform a vacuum pumping operation. When the vacuum pump 600-1 performs the vacuum pumping operation, vacuum pressure may be provided to the substrate S-1 seated on the first surface S1 of the holder 100-1 along the passageway 100P-1. Accordingly, the holder 100-1 may vacuum-adsorb the lower surface of the substrate S-1 (i.e., vacuum suction is used to hold the lower surface of the substrate S-1 to the first surface S1 of the holder 100-1).

The holder 200-1 may be positioned above the holder 100-1. For example, the holder 200-1 and the holder 100-1 may be spaced apart from each other in the second direction D2. The holder 200-1 may include a first surface S3 and a second surface S4 that are opposite to each other in the second direction D2. The first surface S3 may be the upper surface of the holder 200-1, and the second surface S4 may be the lower surface of the holder 200-1.

The holder 200-1 may vacuum-adsorb the semiconductor chip C-1 through a passageway 200P-1 and the vacuum pump 500-1 such that the upper surface of the semiconductor chip C-1 is seated on the second surface S4. The holder 200-1 may include the passageway 200P-1 therein. The passageway 200P-1 may be installed inside the holder 200-1, and may be defined as an empty space extending in the first direction D1 and the second direction D2. The passageway 200P-1 may be connected to the vacuum pump 500-1. The vacuum pump 500-1 may perform a vacuum pumping operation. When the vacuum pump 500-1 performs the vacuum pumping operation, vacuum pressure may be provided to the upper surface of the semiconductor chip C-1 in contact with the second surface S4 of the holder 200-1 along the passageway 200P-1. Accordingly, the holder 200-1 may vacuum-adsorb the upper surface of the semiconductor chip C-1.

FIG. 1 shows the semiconductor chip C-1 mounted on the substrate S-1, but before the semiconductor chip C-1 is mounted on the substrate S-1, the holder 200-1 may move the semiconductor chip C-1 while vacuum-adsorbing it. In this way, the holder 200-1 may pick up the semiconductor chip C-1 and move it onto the substrate S-1 while vacuum-adsorbing it, thereby mounting the semiconductor chip C-1 on the substrate S-1. In this case, the holder 200-1 may align and mount the semiconductor chip C-1 on the substrate S-1 such that the plurality of junctions J-1 formed on the lower surface of the semiconductor chip C-1 are respectively brought into contact with a plurality of pads PD formed on the upper surface of the substrate S-1. The holder 200-1 may continuously vacuum-adsorb the semiconductor chip C-1 even when the semiconductor chip C-1 is aligned and mounted on the substrate S-1 so that the junctions J-1 are in contact with the pads PD.

The bonding apparatus 1000 may further include pressurizing devices CP-1, CP-2, and CP-3. The description of the pressurizing devices CP-2 and CP-3 is the same as the description of the pressurizing device CP-1, and thus the description of the pressurizing devices CP-2 and CP-3 is replaced with the description of the pressurizing device CP-1. The pressurizing device CP-1 may be connected to the first surface S3 of the holder 200-1. The pressurizing device CP-1 may press the holder 200-1 in a direction opposite to the second direction D2, in a state where the holder 200-1 aligns and mounts the semiconductor chip C-1 on the substrate S-1 by vacuum-adsorbing the semiconductor chip C-1. Accordingly, the semiconductor chip C-1 may be pressurized in a direction toward the substrate S-1 while being mounted on the substrate S-1.

The substrate S-1 may include a first surface S5 and a second surface S6 that are opposite to each other in the second direction D2. The first surface S5 may be the upper surface of the substrate S-1, and the second surface S6 may be the lower surface of the substrate S-1. The substrate S-1 may be a printed circuit board (PCB), but is not limited thereto.

When the substrate S-1 is a PCB, the substrate S-1 may be made of at least one material selected from phenolic resin, epoxy resin, and polyimide. The substrate S-1 may include at least one material selected from the group consisting of tetrafunctional epoxy, polyphenylene ether, epoxy/polyphenylene oxide, bismaleimide triazine (BT), Thermount, cyanate ester, and a liquid crystal polymer. The substrate S-1 may contain a resin, e.g., prepreg, Ajinomoto build-up film (ABF), FR-4, or bismaleimide triazine (BT), impregnated into a core material such as glass fiber, glass cloth, or glass fabric, together with an inorganic filler. The plurality of pads PD may be located on the first surface S5 of the substrate S-1 and spaced apart from each other in the first direction D1, as illustrated in FIG. 1.

The semiconductor chip C-1 may be mounted on the substrate S-1. The semiconductor chip C-1 may include a first surface S7 and a second surface S8 that are opposed to each other in the second direction D2. The first surface S7 may be the upper surface of the semiconductor chip C-1, and the second surface S8 may be the lower surface of the semiconductor chip C-1. The plurality of junctions J-1 may be formed on the second surface S8 of the semiconductor chip C-1. The plurality of junctions J-1 may be spaced apart from each other in the first direction D1.

The semiconductor chip C-1 may include, for example, a logic chip such as an application-specific IC (ASIC), a central processing unit (CPU), a graphic processing unit (GPU), a field programmable gate array (FPGA), a digital signal processor (DSP), an encryption processor, a microprocessor, a microcontroller, and an analog-to-digital converter.

In another embodiment, the semiconductor chip C-1 may include a volatile memory device such as a dynamic RAM (DRAM) or a static RAM (SRAM), or a non-volatile memory device such as a phase-change RAM (PRAM), a magnetic RAM (MRAM), a resistive RAM (RRAM), or a flash memory device.

The junctions J-1 may be formed on the second surface S8 of the semiconductor chip C-1 and brought into contact with the pads PD formed on the first surface S5 of the substrate S-1 when the semiconductor chip C-1 is mounted on the substrate S-1. The junctions J-1 may be heated and reflowed while the semiconductor chip C-1 is mounted on the substrate S-1. Through this soldering process, the junctions J-1 may electrically and physically connect the substrate S-1 to the semiconductor chip C-1. The junctions J-1 may be implemented, for example, as solder bumps. The junctions J-1 may include at least one of gold (Au), silver (Ag), copper (Cu), or aluminum (Al).

The induction heating system 300a may include an induction coil 310a and an alternating current (AC) supplying unit 320a. The induction coil 310a may be positioned above the plurality of units U1, U2, and U3 arranged side by side in the first direction D1. The induction coil 310a may contain an electrically conductive material such as copper (Cu) or a Cu alloy. The induction coil 310a may be implemented in a cylindrical shape by winding a ring-shaped conductive wire several times side by side around a single axis. The induction coil 310a may be positioned above the plurality of units U1, U2, and U3 such that the central axis of the ring-shaped conductive wire is parallel to the second direction D2. The number of windings and the number of layers of the induction coil 310a may vary depending on the embodiment. The AC supplying unit 320a may apply an alternating current to the induction coil 310a.

The induction heating system 300a may heat the junctions J-1 by an induction heating method. For example, when an alternating current is applied to the induction coil 310a, an alternating magnetic field may be generated around the induction coil 310a. In this case, an eddy current may be generated in a direction perpendicular to the direction of the magnetic field in a conductor (e.g., the junctions J-1) provided in a region where the alternating magnetic field is generated. The eddy current may flow along the surface of the conductor and may dissipate after generating heat. As such, the eddy current generated in the junctions J-1 may produce their own resistance heat, which may selectively heat a localized portion where the junctions J-1 are located. By this induction heating method, the junctions J-1 may be reflowed and soldered.

The transferring unit 400a may be connected to the induction coil 310a and configured to move the induction coil 310a to the periphery of the plurality of units U1, U2, and U3 (i.e., to move the induction coil 310a along the plurality of units U1, U2, and U3, but in adjacent spaced apart relationship with the plurality of units U1, U2, and U3). The transferring unit 400a may include a power generator, such as a motor, to move the induction coil 310a to a desired position. The transferring unit 400a may move the induction coil 310a in the first direction D1 above the plurality of units U1, U2, and U3, along the plurality of units U1, U2, and U3 arranged in a row in the first direction D1. As the induction coil 310a moves along the first direction D1 above the plurality of units U1, U2, and U3, the induction heating system 300a may sequentially heat the junctions J-1, J-2, and J-3 of the units U1, U2, and U3 to perform a sequential soldering process for the plurality of units U1, U2, and U3.

Although it has been described above that the semiconductor package configuration including the substrate S-1, the semiconductor chip C-1, and the junction J-1 is included in the unit U1, the semiconductor package configuration may be removed from the holder 100-1 and the holder 200-1 after the reflow and soldering process for the semiconductor package configuration is completed. Thereafter, another semiconductor package configuration requiring a soldering process may be positioned between holder 100-1 and holder 200-1.

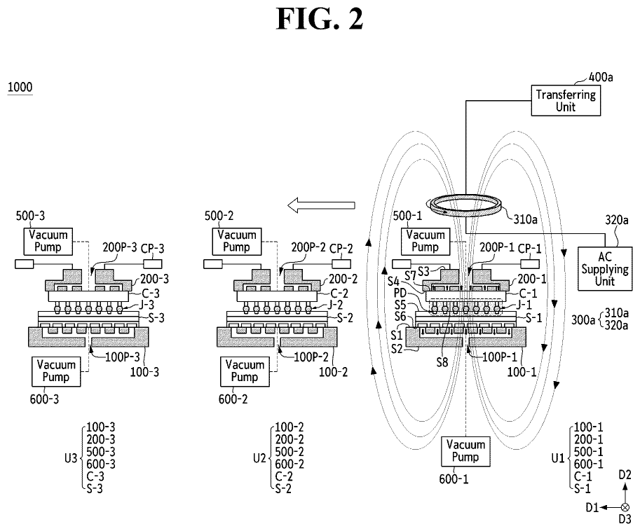

FIGS. 2 to 4 are diagrams for describing an operating method of the bonding apparatus of FIG. 1.

Hereinafter, an operating method of the bonding apparatus 1000 of FIG. 1 will be described with reference to FIGS. 2 to 4.

The transferring unit 400a may move the induction coil 310a such that the induction coil 310a is aligned with the unit U1 in the second direction D2 when a soldering process is required for the junctions J-1 of the unit U1 (FIG. 2). In this case, the induction coil 310a may be spaced apart from the holder 200-1 in the second direction D2. In a state in which the induction coil 310a is aligned above the holder 200-1, the transferring unit 400a may stop the movement of the induction coil 310a. Thereafter, the induction heating system 300a may solder the junctions J-1 through the induction heating method. While the junctions J-1 are being heated, the pressurizing device CP-1 may continuously press the holder 200-1 in a direction toward the holder 100-1. After the soldering for the junctions J-1 is completed, the transferring unit 400a may move the induction coil 310a along the first direction D1.

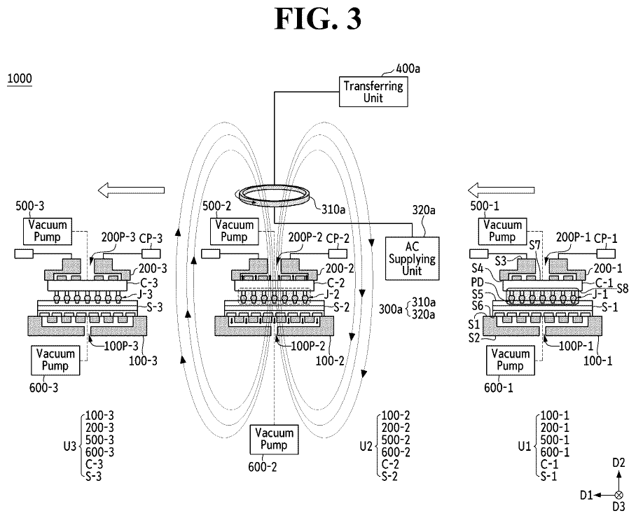

The transferring unit 400a may move the induction coil 310a such that the induction coil 310a is aligned with the unit U2 in the second direction D2 (FIG. 3). In this case, the induction coil 310a may be spaced apart from the holder 200-2 in the second direction D2. In a state in which the induction coil 310a is aligned above the holder 200-2, the transferring unit 400a may stop the movement of the induction coil 310a. Thereafter, the induction heating system 300a may solder the junctions J-2 through the induction heating method. While the junctions J-2 are being heated, the pressurizing device CP-2 may continuously press the holder 200-2 in a direction toward the holder 100-2.

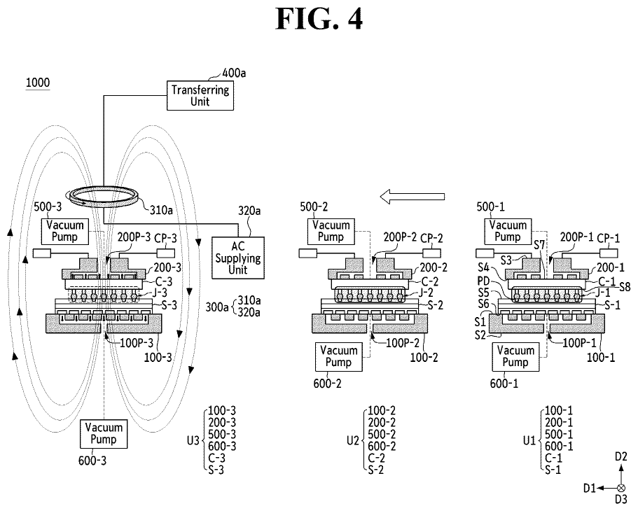

Thereafter, as described above, the transferring unit 400a may further move the induction coil 310a in the first direction D1 to align it above the unit U3 (FIG. 4), and the induction heating system 300a may solder the junctions J-3 through the induction heating method. While the junctions J-3 are being heated, the pressurizing device CP-3 may continue to press the holder 200-3 in a direction toward the holder 100-3.

In this way, by successively performing the soldering process for the plurality of units U1, U2, and U3 arranged in a row in the first direction D1 by moving the induction coil 310a, the productivity of the semiconductor package manufacturing process may be improved.

Meanwhile, when the soldering process for the plurality of units U1, U2, and U3 is performed successively, the units U1, U2, and U3 may be in a fixed state and only the induction coil 310a and the AC supplying unit 320a may move in the first direction D1 to perform the soldering process. For example, taking the unit U1 as an example, the configuration (e.g., the holder 200-1, the vacuum pump 500-1, and the pressurizing device CP-1) for vacuum adsorption and pressurization of the semiconductor chip C-1 and the configuration (e.g., the holder 100-1 and the vacuum pump 600-1) for vacuum adsorption of the substrate S-1 may be kept in a fixed state. In this way, since the configuration for pressurizing and vacuum-adsorbing the semiconductor chip and the substrate is maintained in a fixed state while the soldering process is being performed, the warpage of the semiconductor chip and the substrate may be controlled, and accordingly, a fine pitch of a flip chip process may be achieved.

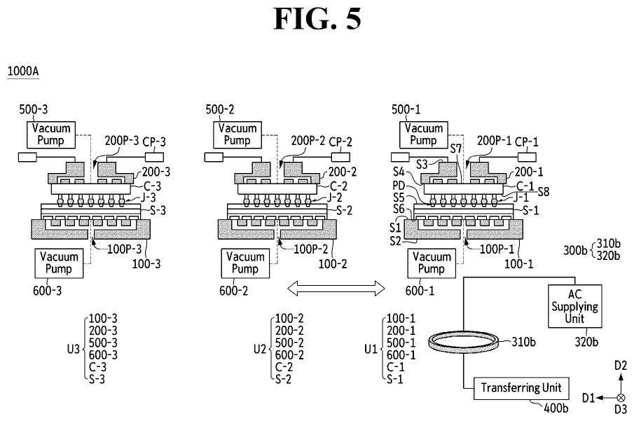

FIG. 5 is a diagram for describing a bonding apparatus according to some embodiments.

In the following description, redundant description of the above-described embodiments will be omitted while focusing on differences.

Referring to FIG. 5, a bonding apparatus 1000A may include an induction heating system 300b. The induction heating system 300b may include an induction coil 310b and an alternating current (AC) supplying unit 320b. The induction coil 310b may be positioned below the plurality of units U1, U2, and U3 arranged side by side in the first direction D1. The induction coil 310b may be positioned below the plurality of units U1, U2, and U3 such that the central axis of the ring-shaped conductive wire is parallel to the second direction D2. A transferring unit 400b may be connected to the induction coil 310b and configured to move the induction coil 310b to the periphery of the plurality of units U1, U2, and U3. Specifically, the transferring unit 400b may move the induction coil 310b in the first direction D1 below the plurality of units U1, U2, and U3, along the plurality of units U1, U2, and U3 arranged in a row in the first direction D1. As the induction coil 310b moves along the first direction D1 below the plurality of units U1, U2, and U3, the induction heating system 300b may sequentially heat the junctions J-1, J-2, and J-3 of the units U1, U2, and U3. In this way, by successively performing the soldering process for the plurality of units U1, U2, and U3 arranged in a row in the first direction D1, the productivity of the semiconductor package manufacturing process may be improved.

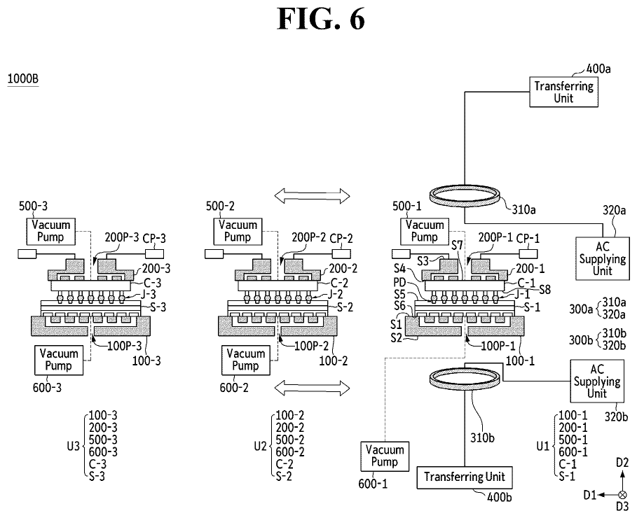

FIG. 6 is a diagram for describing a bonding apparatus according to some embodiments.

Referring to FIG. 6, a bonding apparatus 1000B may include the plurality of induction heating systems 300a and 300b. The induction coil 310a and the induction coil 310b may be moved in the first direction D1 by the transferring unit 400a and the transferring unit 400b, respectively. In addition, an alternating current may be applied to the induction coil 310a and the induction coil 310b by the AC supplying unit 320a and the AC supplying unit 320b, respectively.

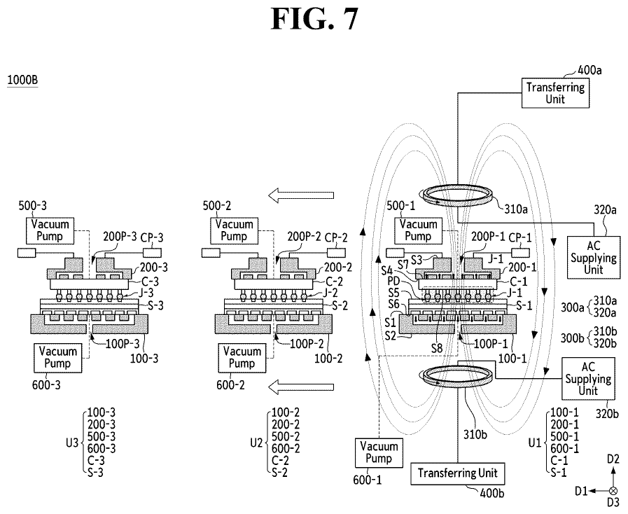

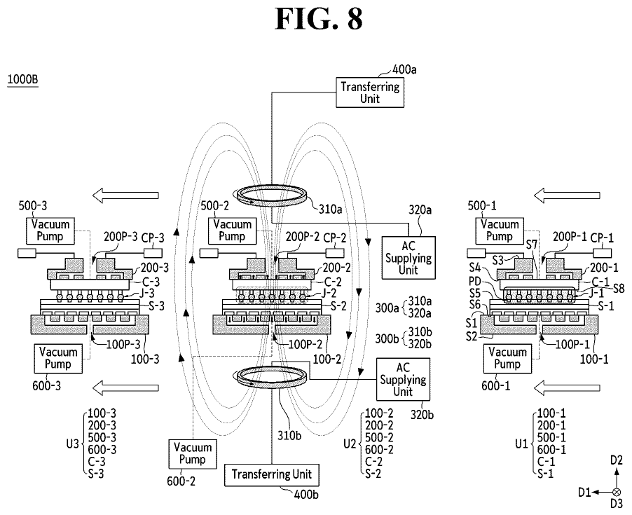

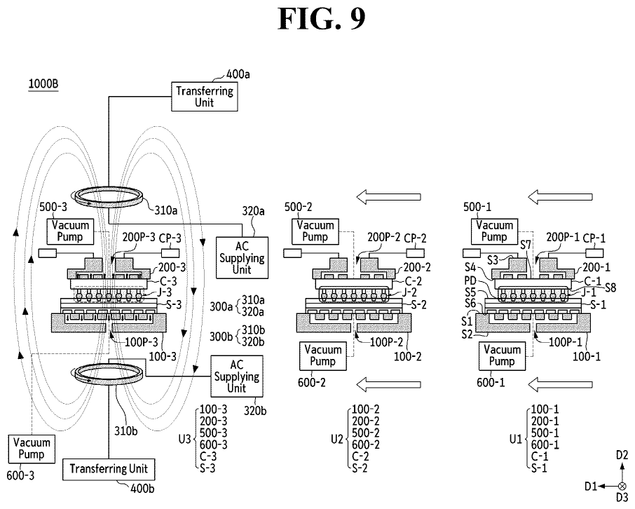

Simultaneously with the induction coil 310a being moved along the first direction D1 by the transferring unit 400a, the induction coil 310b may also be moved along the first direction D1 by the transferring unit 400b. An operating method of the bonding apparatus 1000B of FIG. 6 will be described later with reference to FIGS. 7 to 9.

FIGS. 7 to 9 are diagrams for describing an operating method of the bonding apparatus of FIG. 6.

When a soldering process is required for the junction J-1 of the unit U1, the transferring units 400a and 400b may move the induction coils 310a and 310b, respectively, such that the induction coil 310a and the induction coil 310b are aligned in the second direction D2 with the unit U1 interposed therebetween. In this case, the induction coil 310a may be spaced apart from the holder 200-1 in the second direction D2, and the induction coil 310b may be spaced apart from the holder 100-1 in the opposite direction of the second direction D2. That is, the induction coil 310a may be positioned above the first surface S3, which is a surface opposite to the holder 100-1 between the first surface S3 and the second surface S4 of the holder 200-1, and the induction coil 310b may be positioned below the second surface S2, which is a surface opposite to the holder 200-1 between the first surface S1 and the second surface S2 of the holder 100-1.

In a state in which the induction coil 310a is aligned above the holder 200-1 and the induction coil 310b is aligned below the holder 100-1, the transferring units 400a and 400b may stop the movement of the induction coils 310a and 310b, respectively.

Thereafter, the AC supplying unit 320a may apply an alternating current to the induction coil 310a to induce an alternating magnetic field around the induction coil 310a, and the AC supplying unit 320b may apply an alternating current to the induction coil 310b to induce an alternating magnetic field around the induction coil 310b.

Accordingly, the resistance heat generated by the alternating magnetic field induced around the induction coil 310a and the resistance heat generated by the alternating magnetic field induced around the induction coil 310b may be simultaneously applied to the junction J-1. In this way, the reflow and soldering of the junction may be further enhanced when the induction coil that generates resistance heat to heat the junction is positioned both above and below the plurality of units U1, U2, and U3, as compared to an embodiment in which the induction coil is positioned only above the plurality of units U1, U2, and U3 as shown in FIG. 1, or only below the plurality of units U1, U2, and U3 as shown in FIG. 5.

After the soldering for the junction J-1 is completed, the transferring unit 400a may move the induction coil 310a along the first direction D1, and at the same time, the transferring unit 400b may also move the induction coil 310b along the first direction D1.

The transferring unit 400a may move the induction coil 310a in the first direction D1 until the induction coil 310a is aligned with the unit U2 in the second direction D2, and at the same time, the transferring unit 400b may move the induction coil 310b in the first direction D1 until the induction coil 310b is aligned with the unit U2 in the second direction D2. In a state in which the induction coil 310a is aligned above the holder 200-1, the transferring unit 400a may stop the movement of the induction coil 310a, and in a state in which the induction coil 310b is aligned below the holder 100-1, the transferring unit 400b may stop the movement of the induction coil 310b. Thereafter, the induction heating systems 300a and 300b may simultaneously apply resistance heat to the junction J-2 through the induction heating method to solder the junction J-2.

Then, as described above, the transferring units 400a and 400b may further move the induction coils 310a and 310b in the first direction D1 to align them above and below the unit U3, respectively, and the induction heating systems 300a and 300b may solder the junction J-3 through the induction heating method. In this way, the soldering process for the plurality of units U1, U2, and U3 may be performed successively by moving the induction coils 310a and 310b, which are separately positioned above and below the plurality of units U1, U2, and U3 arranged in a row in the first direction D1, using separate transferring units 400a and 400b, respectively. By doing so, in a process of manufacturing a semiconductor package in which the semiconductor chip is mounted on the substrate, the electrical connectivity between the semiconductor chip and the substrate may be improved. In addition, the productivity of the semiconductor package manufacturing process may be improved.

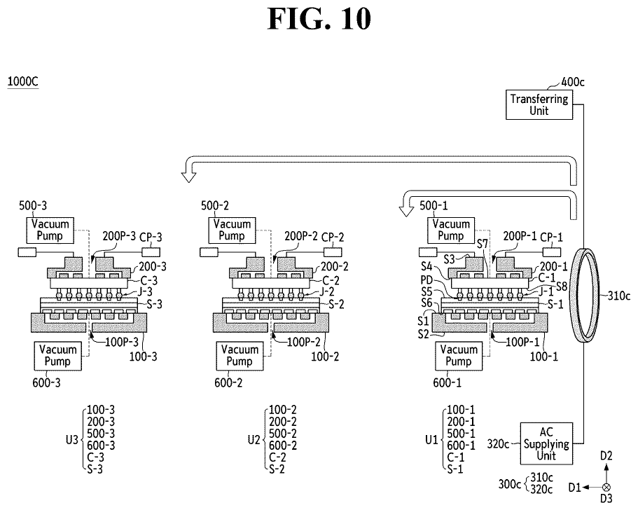

FIG. 10 is a diagram for describing a bonding apparatus according to some embodiments.

Referring to FIG. 10, a bonding apparatus 1000C may include an induction heating system 300c and a transferring unit 400c. The induction heating system 300c may include an induction coil 310c and an alternating current (AC) supplying unit 320c. When the induction heating system 300c performs a soldering process for the plurality of units U1, U2, and U3 by heating the junctions J-1, J-2, and J-3, the induction coil 310c may be positioned at the lateral side of the unit to be soldered. For example, as shown in FIG. 10, when performing a soldering process for the unit U1, the transferring unit 400c may move the induction coil 310c such that the induction coil 310c is positioned at the lateral side of the unit U1 in a direction opposite to the first direction D1 of the unit U1 between both lateral sides of the unit U1 in the first direction D1. In this case, the induction coil 310c may be positioned at the lateral side of the unit U1 such that the central axis of the ring-shaped conductive wire is parallel to the first direction D1.

In a state in which the induction coil 310c is positioned at the lateral side of the unit U1, the induction heating system 300c may heat the junction J-1 by inducing an alternating magnetic field around the induction coil 310c. Accordingly, the junction J-1 may be soldered.

After the soldering process for the junction J-1 of the unit U1 is completed, the transferring unit 400c may move the induction coil 310c in the first direction D1 to position the induction coil 310c to the lateral side of the unit U2 in a direction opposite to the first direction D1. In this case, the transferring unit 400c may allow the induction coil 310c to pass above the top of the unit U1 and be positioned between the unit U1 and the unit U2. However, the embodiment is not limited thereto, and the transferring unit 400c may allow the induction coil 310c to pass below the bottom of the unit U1 and be positioned between the unit U1 and the unit U2.

In a state in which the induction coil 310c is positioned between the unit U1 and the unit U2, the induction heating system 300c may heat the junction J-2 by inducing an alternating magnetic field around the induction coil 310c. Accordingly, the junction J-2 may be soldered.

After the soldering process for the junction J-2 of the unit U2 is completed, the transferring unit 400c may, in the same manner, allow the induction coil 310c to pass above the top of the unit U2 and be positioned between the unit U2 and the unit U3. In a state in which the induction coil 310c is positioned at the lateral side of the unit U3 in a direction opposite to the first direction D1, the induction heating system 300c may heat and solder the junction J-3 by inducing an alternating magnetic field around the induction coil 310c.

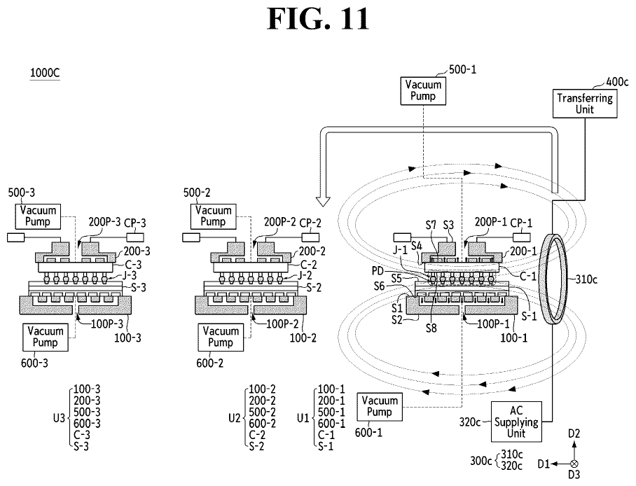

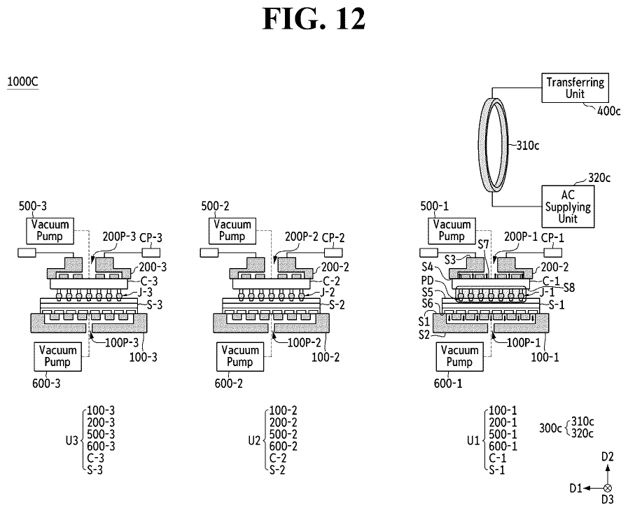

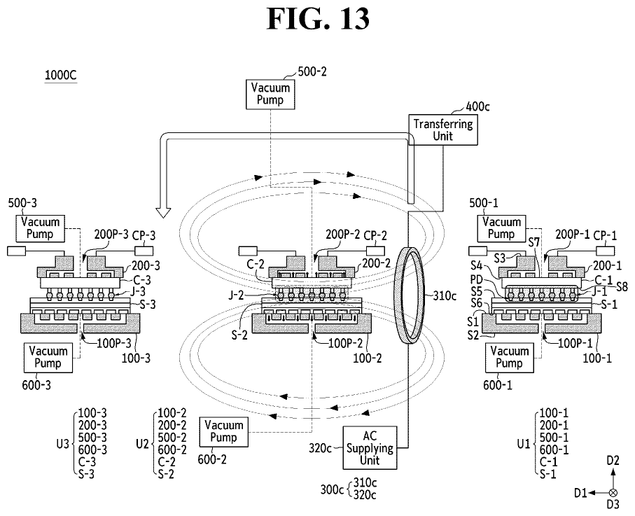

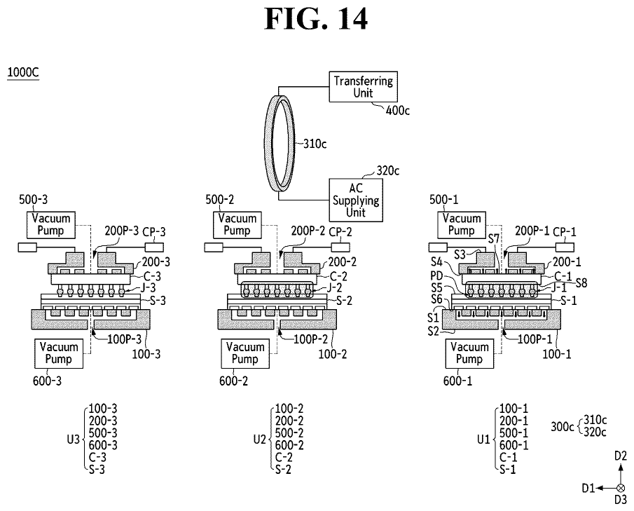

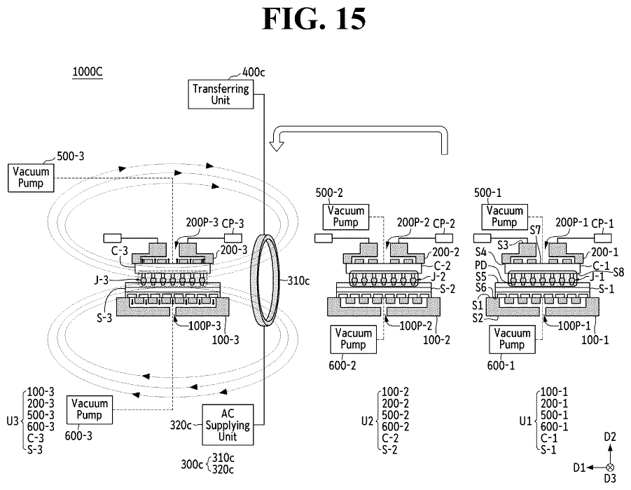

FIGS. 11 to 15 are diagrams for describing an operating method of the bonding apparatus of FIG. 10.

Hereinafter, an operating method of the bonding apparatus 1000C of FIG. 1 will be described with reference to FIGS. 11 to 15.

When a soldering process is required for the junction J-1 of the unit U1, the transferring unit 400c may move the induction coil 310c such that the induction coil 310c is aligned with the unit U1 in the first direction D1. In this case, the induction coil 310c may be spaced apart from the unit U1 in a direction opposite to the first direction D1. In a state in which the induction coil 310c is aligned with the unit U1 in the first direction D1, the transferring unit 400c may stop the movement of the induction coil 310c.

Subsequently, the AC supplying unit 320c may apply an alternating current to the induction coil 310c. When an alternating current is applied to the induction coil 310c, an alternating magnetic field may be generated around the induction coil 310c. In this case, the junction J-1 may be provided in a region where the alternating magnetic field is generated, and an eddy current may be generated in the junction J-1 including a conductor. The junction J-1 may be selectively heated by its own resistance heat generated by the eddy current and may be reflowed and soldered.

In this case, the holder 200-1 may continue to vacuum-adsorb the semiconductor chip C-1 through the vacuum pump 500-1. Similarly, the holder 100-1 may continuously vacuum-adsorb and support the substrate S-1 through the vacuum pump 600-1. Accordingly, while the reflow and soldering process for the junction J-1 is performed, the semiconductor chip C-1 and the substrate S-1 may be maintained in a fixed state, thereby preventing warpage defects.

After the soldering for the junction J-1 is completed, the transferring unit 400c may move the induction coil 310c in the second direction D2 and the first direction D1. Specifically, the transferring unit 400c may move the induction coil 310c such that the induction coil 310c passes above the top of the unit U1 and is positioned between the unit U1 and the unit U2.

The transferring unit 400c may position the induction coil 310c to the lateral side of the unit U2 in a direction opposite to the first direction D1 such that the induction coil 310c is aligned with the unit U2 in the first direction D1. In this case, the induction coil 310c may be spaced apart from the unit U2 in a direction opposite to the first direction D1. In a state in which the induction coil 310c is aligned with the unit U2 in the first direction D1, the transferring unit 400c may stop the movement of the induction coil 310c.

Thereafter, the AC supplying unit 320c may apply an alternating current to the induction coil 310c, and the junction J-2 may be selectively heated by the alternating magnetic field induced around the induction coil 310c and may be reflowed and soldered. In this case, the holder 200-1 may continue to vacuum-adsorb the semiconductor chip C-1, and the holder 100-1 may continue to support and vacuum-adsorb the substrate S-1. Accordingly, while the induction coil 310c moves and sequentially performs the reflow process for the plurality of units U1, U2, and U3, the substrate S-1 and the semiconductor chip C-1 mounted on the substrate S-1 may be maintained in a fixed state, thereby reducing the possibility of warpage defects.

Subsequently, as described above, the transferring unit 400c may further move the induction coil 310c in the first direction D1 to pass above the top of the unit U2 and be positioned between the unit U2 and the unit U3, and align the induction coil 310c with the unit U3 in the first direction D1. Thereafter, the induction heating system 300c may reflow and solder the junction J-3 through the induction heating method. In this way, by successively performing the soldering process for the plurality of units U1, U2, and U3 arranged in a row in the first direction D1 by moving the induction coil 310c while the remaining components (e.g., the semiconductor chip C-1, the substrate S-1, the holder 100-1, the holder 200-1, and the like) of the bonding apparatus 1000C, except for the induction coil 310c, the AC supplying unit 320c, and the transferring unit 400c, are fixed, the productivity of the semiconductor package manufacturing process may be improved.

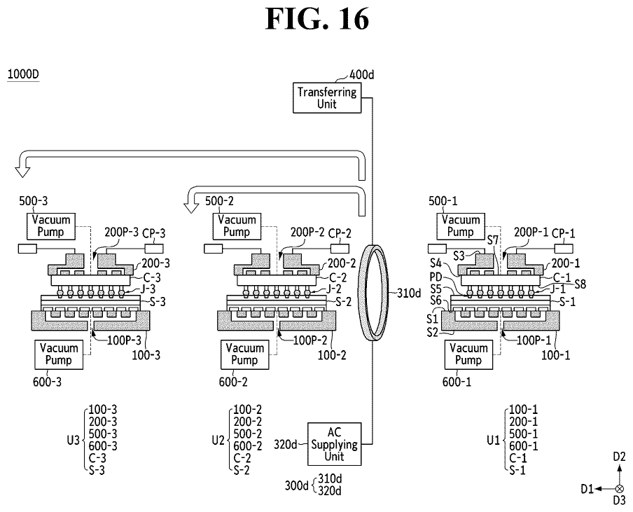

FIG. 16 is a diagram for describing a bonding apparatus according to some embodiments.

Referring to FIG. 16, a bonding apparatus 1000D may include an induction heating system 300d. The induction heating system 300d may include an induction coil 310d and an AC supplying unit 320d. When the induction heating system 300d performs a soldering process for the plurality of units U1, U2, and U3 by heating the junctions J-1, J-2, and J-3, the induction coil 310d may be positioned at the lateral side of the unit to be soldered, as illustrated. For example, as shown in FIG. 16, when performing a soldering process for the unit U1, a transferring unit 400d may move the induction coil 310d such that the induction coil 310d is positioned at a lateral side of the unit U1 in the first direction D1. In this case, the induction coil 310d may be positioned at the lateral side of the unit U1 such that the central axis of the ring-shaped conductive wire is parallel to the first direction D1.

The transferring unit 400d may be connected to the induction coil 310d and configured to move the induction coil 310d to the periphery of the plurality of units U1, U2, and U3. Specifically, the transferring unit 400d may move the induction coil 310a in the first direction D1 and the second direction D2 to position the induction coil 310d between the unit U2 and the unit U3 when the soldering process for the unit U2 is performed, and to position the induction coil 310d to the lateral side of the unit U3 in the first direction D1 when the soldering process for the unit U3 is performed.

When the transferring unit 400d transfers the induction coil 310d between the plurality of units U1, U2, and U3, it may move the induction coil 310d to pass above the top of each of the units U1, U2, and U3. However, the embodiment is not limited thereto, and when the transferring unit 400d transfers the induction coil 310d between the plurality of units U1, U2, and U3, it may move the induction coil 310d to pass below the bottom of each of the units U1, U2, and U3.

In this way, in a state in which the plurality of units U1, U2, and U3 arranged in a row along the first direction D1 are fixed and the induction coil 310d is moved by the transferring unit 400d and be positioned to the lateral side of each of the plurality of units U1, U2, and U3, the junctions J-1, J-2, and J-3 of the units U1, U2, and U3 may be selectively heated, so that they may be sequentially reflowed and soldered.

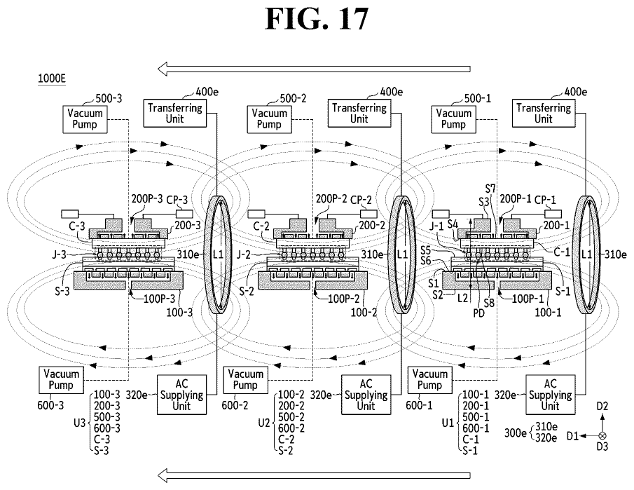

FIG. 17 is a diagram for describing a bonding apparatus according to some embodiments.

Referring to FIG. 17, a bonding apparatus 1000E may include an induction heating system 300e and a transferring unit 400c. The induction heating system 300e may include an induction coil 310e and an alternating current (AC) supplying unit 320e. The transferring unit 400e may move the induction coil 310e in the first direction D1 to sequentially heat and solder the junctions J-1, J-2, and J-3 of the plurality of units U1, U2, and U3 arranged in the first direction D1.

The induction coil 310e may be positioned such that the central axis of the ring-shaped conductive wire is parallel to the first direction D1. The transferring unit 400e may move the induction coil 310e in the first direction D1 such that the plurality of units U1, U2, and U3 sequentially pass through the ring-shaped induction coil 310e. When the induction coil 310c is transferred in the first direction D1 by the transferring unit 400e, the plurality of units U1, U2, and U3 may be in a fixed state.

In this case, a length L1 of the ring-shaped induction coil 310e in the second direction D2 may be greater than the length of each of the plurality of units U1, U2, and U3 in the second direction D2 such that each of the plurality of units U1, U2, and U3 can pass through the induction coil 310e. In this case, the length L1 of the ring-shaped induction coil 310e in the second direction D2 may be defined as an inner diameter of the induction coil 310c. Taking the unit U1 as an example, a length L2 measured in the second direction D2 from the second surface S2 of the holder 100-1 to the first surface S3 of the holder 200-1 may be smaller than the length L1 of the induction coil 310e in the second direction D2 (L1>L2).

In this way, as the induction coil 310e is moved in the first direction D1 by the transferring unit 400e such that the plurality of units U1, U2, and U3 arranged side by side in the first direction D1 and in a fixed state sequentially pass through the ring of the induction coil 310e, the soldering process for the plurality of units U1, U2, and U3 may be successively performed, thereby improving the productivity of the semiconductor package manufacturing process.

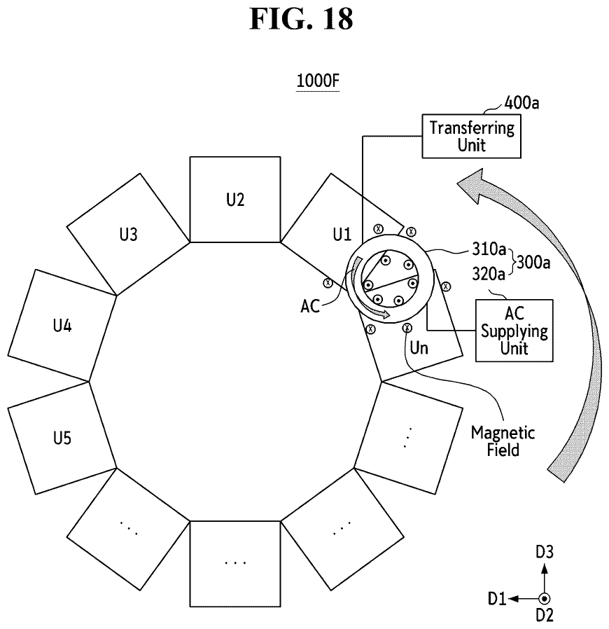

FIG. 18 is a diagram for describing a bonding apparatus according to some embodiments.

Referring to FIG. 18, a bonding apparatus 1000F may include a plurality of units U1, U2, U3, . . . , Un (where n is any natural number), the induction heating system 300a, and the transferring unit 400a.

The plurality of units U1, U2, U3, . . . , Un may be arranged in a circular configuration. Each of the plurality of units U1, U2, U3, . . . , Un may be the same as each of the plurality of units U1, U2, and U3 described with reference to FIGS. 1 to 17. Therefore, a detailed description of the plurality of units U1, U2, U3, . . . , Un will be omitted.

The induction heating system 300a may include the induction coil 310a and the AC supplying unit 320a. The induction coil 310a may be positioned above the plurality of units U1, U2, U3, . . . , Un arranged in a circular configuration. Specifically, the induction coil 310a may be positioned so as to be spaced apart from the plurality of units U1, U2, U3, . . . , Un in the second direction D2. The transferring unit 400a may be connected to the induction coil 310a and may move the induction coil 310a to the periphery of the plurality of units U1, U2, U3, . . . , Un. Specifically, the transferring unit 400a may move the induction coil 310a in a circular manner along the plurality of units U1, U2, U3, . . . , Un that are arranged in a circular configuration (i.e., the transferring unit 400a is configured to move the induction coil 310a along a circular path that maintains the induction coil 310a in adjacent spaced apart relationship with the plurality of units U1, U2, U3, . . . , Un).

For example, the induction coil 310a may be stopped above the unit U1 in a state aligned with the unit U1 in the second direction D2. Then, the AC supplying unit 320a may apply an alternating current to the induction coil 310a to selectively heat and solder the junction J-1 (see FIG. 1) included in the unit U1. After the reflow and soldering process for the junction J-1 included in the unit U1 is completed, the transferring unit 400a may move the induction coil 310a in a counterclockwise direction to position the induction coil 310a above the unit U2 such that the induction coil 310a is aligned with the unit U2 in the second direction D2. Thereafter, the AC supplying unit 320a may apply an alternating current to the induction coil 310a to selectively heat and solder the junction J-2 (see FIG. 1) included in the unit U2.

Although the transferring unit 400a has been described above as transferring the induction coil 310a in a counterclockwise direction, the transferring unit 400a may move the induction coil 310a in a circular manner (i.e., along a circular or arcuate path) irrespective of direction.

In this way, while the transferring unit 400a transfers the induction coil 310a in a circular manner along the plurality of units U1, U2, U3, . . . , Un arranged in a circular configuration, the junctions of the plurality of units U1, U2, U3, . . . , Un may be sequentially heated, and thus a sequential soldering process for the plurality of units U1, U2, U3, . . . , Un may be performed.

As such, by successively performing a soldering process for the plurality of units U1, U2, U3, . . . , Un arranged in a circular configuration by moving the induction coil 310a while the semiconductor package configuration to be soldered and the holders supporting and fixing the semiconductor package configuration are fixed, the productivity of the semiconductor package manufacturing process may be improved.

Although the induction coil 310a has been described above as being positioned above the plurality of units U1, U2, U3, . . . , Un arranged in a circular configuration, the embodiment is not limited thereto. For example, as described with reference to FIG. 5, the induction coil 310a may be positioned below the plurality of units U1, U2, U3, . . . , Un. In this case, the transferring unit 400a transfers the induction coil 310a in a circular manner below the plurality of units U1, U2, U3, . . . , Un arranged in a circular configuration to allow the plurality of units U1, U2, U3, . . . , Un to be sequentially heated.

In another embodiment, the induction coil 310a may be implemented as a plurality of coils. For example, as described with reference to FIG. 6, the induction coil 310a may be positioned both above and below the plurality of units U1, U2, U3, . . . , Un. In this case, the induction coils may be simultaneously moved in a circular manner above and below the plurality of units U1, U2, U3, . . . , Un by separate transferring units to perform a sequential soldering process.

Referring again to FIG. 1, after the soldering process for the semiconductor package configuration (the substrate S-1, the semiconductor chip C-1 positioned on the substrate S-1, and the like) included in the unit U1 is completed, the substrate S-1 and the semiconductor chip C-1 mounted on the substrate S-1 may be removed from the holder 100-1. Then, another substrate may be mounted on the holder 100-1, and the holder 200-1 may pick up another semiconductor chip and align and mount it on the substrate S-1.

As for the units U2 and U3, when the soldering process for the semiconductor package configuration is completed, the corresponding semiconductor package may be removed, and then another substrate and semiconductor chip may be supported and fixed by the holder for the soldering process. In this case, the transferring unit 400a may move the induction coil 310a in the first direction D1 so that a successive and sequential soldering process is performed for the plurality of units U1, U2, and U3 arranged in the first direction D1. After the sequential soldering process for the unit U1 and the unit U2 is performed, and finally the soldering process for the unit U3 is performed, the transferring unit 400a may again move the induction coil 310a to be positioned above the unit U1. Thereafter, the transferring unit 400a may move the induction coil 310a again in the first direction D1 to allow a semiconductor package configuration newly provided to each of the units U1, U2, and U3 to be sequentially soldered.

Meanwhile, referring to FIG. 18, since the plurality of units U1, U2, U3, . . . , Un are arranged in a circular configuration, the reflow and soldering processes for the plurality of units U1, U2, U3, . . . , Un may be performed while the transferring unit 400a continuously circulates, unlike the operation method of the bonding apparatus described with reference to FIGS. 1 to 17, in which, after the soldering process for the last unit of the plurality of units arranged in a row in the first direction D1 is completed, the transferring unit 400a returns to the first unit where the soldering process was started. Accordingly, the productivity of the semiconductor package manufacturing process may be improved.

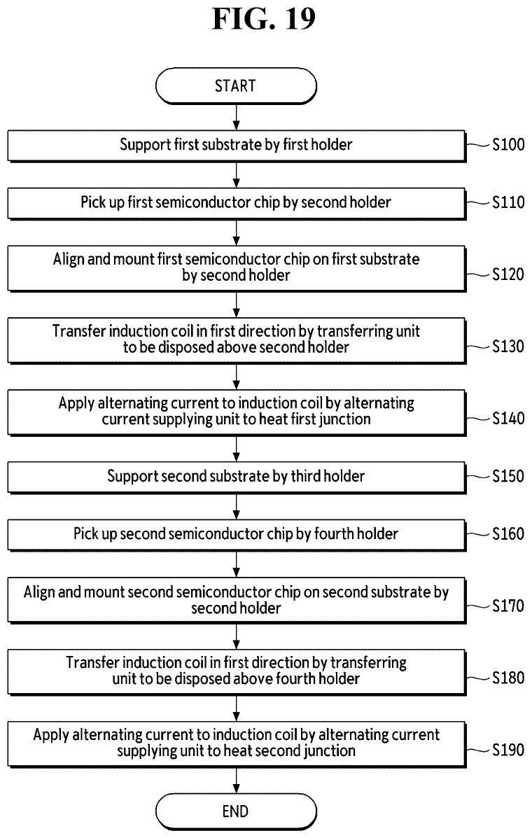

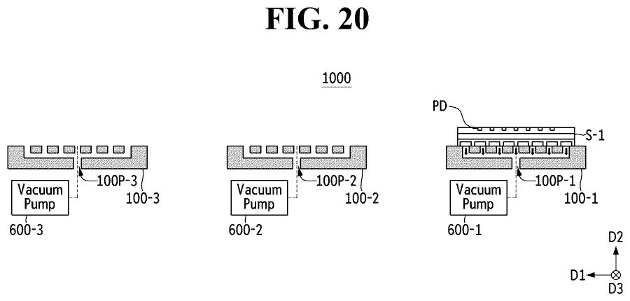

FIG. 19 is a flowchart illustrating an operating method of a bonding apparatus according to some embodiments. FIGS. 20 to 28 are diagrams for describing an operating method of a bonding apparatus according to the flowchart of FIG. 19.

Hereinafter, an operating method of a bonding apparatus according to some embodiments will be described with reference to FIGS. 19 to 28.

First, referring to FIGS. 19 and 20, the substrate S-1 may be mounted on the holder 100-1 and supported by the holder 100-1 (step S100). The substrate S-1 may be mounted on the holder 100-1 such that the second surface S6 of the substrate S-1 faces the first surface S1 of the holder 100-1. The vacuum pump 600-1 may perform a vacuum pumping operation on the second surface S6 of the substrate S-1 to fix the substrate S-1 on the holder 100-1. The first surface S5 of the substrate S-1 may have the plurality of pads PD formed thereon. In this case, the holder 100-2 constituting the unit U2 and the holder 100-3 constituting the unit U3 may be arranged side by side with the holder 100-1 in the first direction D1. The substrates S-2 and S-3 may not yet be positioned on the holder 100-2 and the holder 100-3.

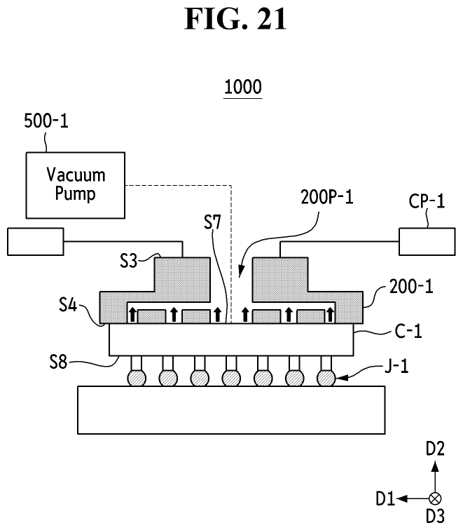

Next, referring to FIGS. 19 and 21, the semiconductor chip C-1 may be picked up by the holder 200-1 (step S110). The holder 200-1 may pick up the semiconductor chip C-1 by vacuum-adsorbing the first surface S7 of the semiconductor chip C-1 through the vacuum pump 500-1. In this case, the second surface S8 of the semiconductor chip C-1 may have the plurality of junctions J-1 formed thereon.

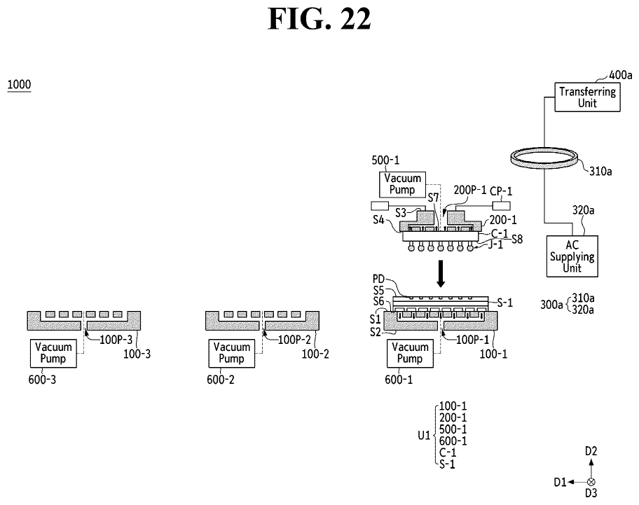

Next, referring to FIGS. 19 and 22, the holder 200-1 may align and mount the picked-up semiconductor chip C-1 on the substrate S-1 (step S120). The holder 200-1 may align and mount the semiconductor chip C-1 on the substrate S-1 such that the junctions J-1 are respectively brought into contact with the pads PD. In this case, the pressurizing device CP-1 may press the holder 200-1 in a direction opposite to the second direction D2 such that the semiconductor chip C-1 is fixed on the substrate S-1.

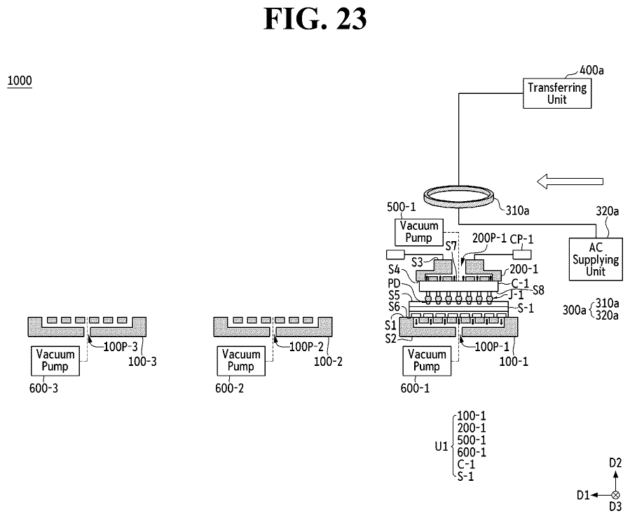

Next, referring to FIGS. 19 and 23, the transferring unit 400a may move the induction coil 310a in the first direction D1 to position the induction coil 310a above the holder 200-1 (step S130). The transferring unit 400a may position the induction coil 310a so as to be spaced apart from the holder 200-1 in the second direction D2 such that the induction coil 310a is aligned with the substrate S-1 mounted on the holder 100-1 and the semiconductor chip C-1 in the second direction D2. The transferring unit 400a may stop the movement of the induction coil 310a when the induction coil 310a is aligned above the holder 200-1.

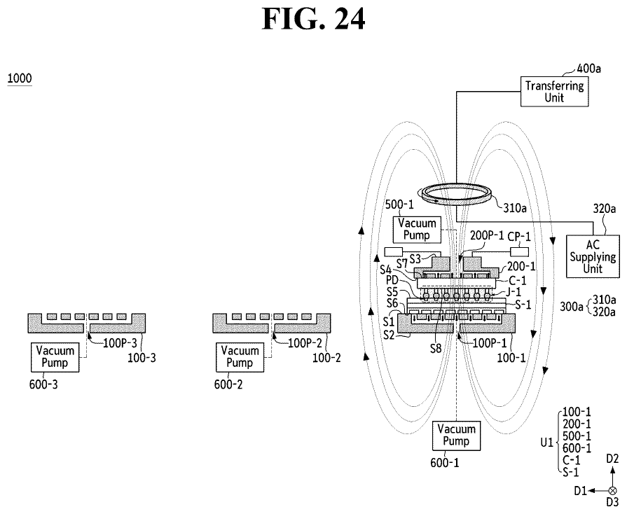

Next, referring to FIGS. 19 and 24, the AC supplying unit 320a may apply an alternating current to the induction coil 310a to heat the junction J-1 (step S140). While performing the soldering process for the unit U1 in this way, the soldering process for the unit U2, which will be soldered next, may be prepared.

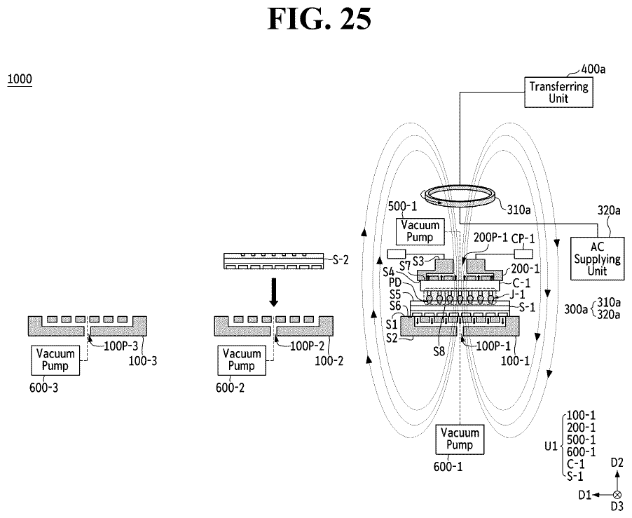

For example, referring to FIGS. 19 and 25, at step S140, while the induction heating system 300a is heating the junction J-1, the substrate S-2 may be mounted on the holder 100-2 and supported by the holder 100-2 (step S150).

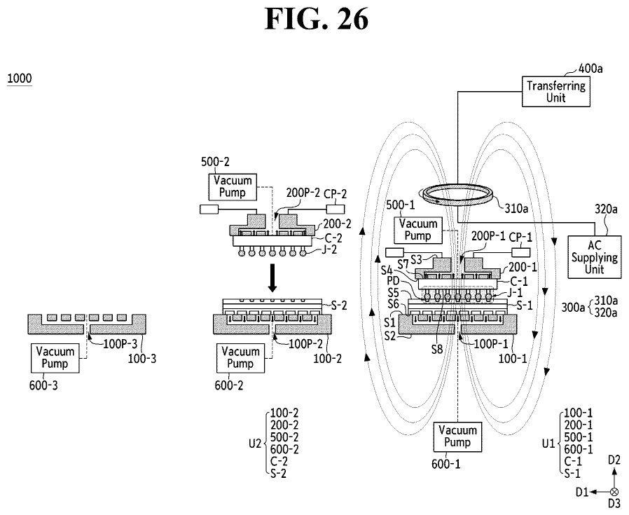

Next, referring to FIGS. 19 and 26, the semiconductor chip C-2 may be picked up by the holder 200-2 (step S160). The holder 200-2 may pick up the semiconductor chip C-2 by vacuum-adsorbing the upper surface of the semiconductor chip C-2 through the vacuum pump 500-2. In this case, the lower surface of the semiconductor chip C-2 may have the plurality of junctions J-2 formed thereon.

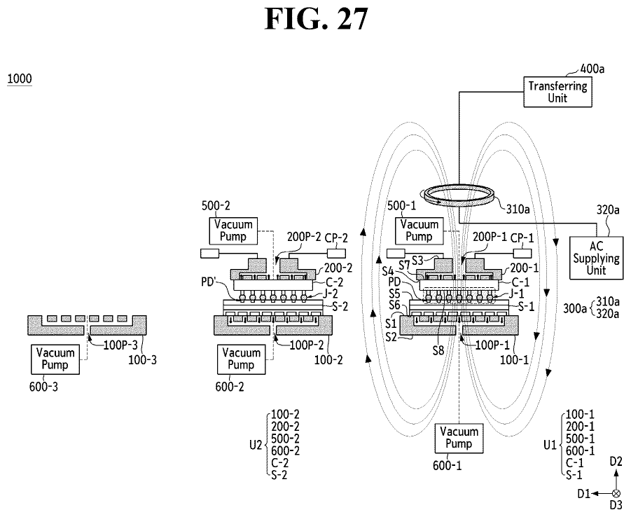

Next, referring to FIGS. 19 and 27, the holder 200-2 may align and mount the picked-up semiconductor chip C-2 on the substrate S-2 (step S170). In this case, the holder 200-2 may align and mount the semiconductor chip C-2 on the substrate S-2 such that the junctions J-2 are respectively brought into contact with pads PD′ formed on the upper surface of the substrate S-2. In this way, the soldering process for the unit U1 may continue to be performed while the semiconductor package configuration (e.g., the substrate S-2 and the chip C-2) is being mounted on the holder 100-2 to prepare the soldering process for the unit U2 during steps S150 to S170.

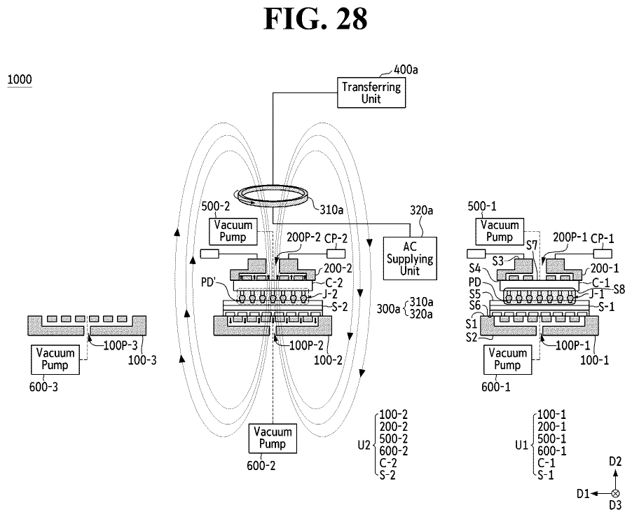

Next, referring to FIGS. 19 and 28, when the soldering process for the unit U1 is completed, the transferring unit 400a may move the induction coil 310a in the first direction D1 to position the induction coil 310a above the holder 200-2 (step S180). Subsequently, the AC supplying unit 320a may apply an alternating current to the induction coil 310a to heat the junction J-2 (step S190).

In a manner similar to that described above, while the soldering process for the unit U2 is being performed, the soldering process for the unit U3, which will be soldered next, may be prepared.

In this way, when a soldering process is successively performed for the plurality of units U1, U2, and U3 arranged side by side in the first direction D1 by transferring the induction coil 310a in the first direction D1, a preparation process of picking up the semiconductor chip and aligning and mounting it on the substrate may be performed in advance before the induction coil 310a is moved, in other words, while the junction included in another unit is being heated. This may increase the productivity of the semiconductor package manufacturing process.

What is claimed is:

1. A bonding apparatus comprising:
a plurality of units, each of the plurality of units comprising a first holder configured to support a substrate and a semiconductor chip with a junction therebetween, and a second holder above the first holder, wherein the second holder is configured to mount the semiconductor chip on the substrate and apply pressure to the semiconductor chip, wherein the plurality of units are arranged in adjacent spaced apart relationship along a first direction;
an induction heating system comprising a first induction coil and a first alternating current supplying unit configured to apply an alternating current to the first induction coil, wherein the induction heating system is configured to heat the junction between the substrate and the semiconductor chip at each of the plurality of units by inducing a magnetic field around the first induction coil; and
a first transferring unit connected to the first induction coil, wherein the first transferring unit is configured to position the first induction coil adjacent each of the plurality of units,
wherein the first transferring unit is configured to move the first induction coil along the first direction, and wherein the induction heating system is configured to sequentially heat respective junctions between the semiconductor chip and the substrate at each of the plurality of units as the first induction coil moves along the first direction.

2. The bonding apparatus of claim 1, further comprising a vacuum pump in fluid communication with a passageway inside the second holder,
wherein the second holder is configured to pick up the semiconductor chip by vacuum-adsorbing the semiconductor chip as vacuum is applied to the passageway by the vacuum pump, and align and mount the semiconductor chip on the substrate.

3. The bonding apparatus of claim 1, further comprising a vacuum pump in fluid communication with a passageway inside the first holder,
wherein the first holder has a surface configured to support the substrate, and
wherein the first holder is configured to vacuum-adsorb the substrate supported on the surface as vacuum is applied to the passageway by the vacuum pump.

4. The bonding apparatus of claim 1, wherein the first holder and the second holder are spaced apart from each other in a second direction that is transverse to the first direction,
wherein the second holder has a first surface facing the first holder and a second surface opposite to the first surface in the second direction, and
wherein the first induction coil is positioned in adjacent spaced apart relationship with the second surface of the second holder in the second direction.

5. The bonding apparatus of claim 1, wherein the first holder and the second holder are spaced apart from each other in a second direction that is transverse to the first direction,
wherein the first holder has a first surface facing the second holder and a second surface opposite to the first surface in the second direction, and
wherein the first induction coil is positioned in adjacent spaced apart relationship with the second surface of the first holder.

6. The bonding apparatus of claim 1, wherein the induction heating system further comprises a second induction coil and a second alternating current supplying unit configured to apply an alternating current to the second induction coil, and
wherein the induction heating system is configured to heat the junction between the semiconductor chip and the substrate at each of the plurality of units by inducing a magnetic field around the second induction coil.

7. The bonding apparatus of claim 6, further comprising a second transferring unit connected to the second induction coil, wherein the second transferring unit is configured to move the second induction coil along the first direction.

8. The bonding apparatus of claim 7, wherein the first transferring unit and the second transferring unit are configured to respectively move the first induction coil and the second induction coil simultaneously along the first direction, and wherein the induction heating system is configured to heat the junction between the semiconductor chip and the substrate at each of the plurality of units sequentially as the first induction coil and the second induction coil are moved along the first direction.

9. The bonding apparatus of claim 6, wherein the first holder and the second holder are spaced apart from each other in a second direction that is transverse to the first direction,
wherein one of the first induction coil and the second induction coil is positioned in adjacent spaced apart relationship with a surface of the first holder, and
wherein the other one of the first induction coil and the second induction coil is positioned in adjacent spaced apart relationship with a surface of the second holder.

10. The bonding apparatus of claim 1, further comprising a pressurizing device connected to the second holder, wherein the pressurizing device is configured to press the second holder toward the first holder.

11. The bonding apparatus of claim 10, wherein the induction heating system is configured to heat the junction between the semiconductor chip and the substrate at each of the plurality of units at the same time as the pressurizing device presses the second holder toward the first holder.

12. The bonding apparatus of claim 1, wherein the plurality of units comprise a first unit, a second unit, and a third unit arranged sequentially along the first direction,
wherein the first transferring unit is configured to move the first induction coil to a position between the first unit and the second unit, and
wherein the induction heating system is configured to heat the junction between the semiconductor chip and the substrate at the second unit.

13. The bonding apparatus of claim 12, wherein, after heating the junction between the semiconductor chip and the substrate at the second unit, the first transferring unit is configured to move the first induction coil to a position between the second unit and the third unit, and
wherein the induction heating system is configured to heat the junction between the semiconductor chip and the substrate at the third unit.

14. A bonding apparatus comprising:
a plurality of units, each of the plurality of units comprising a first holder configured to support a substrate and a semiconductor chip with a junction therebetween, and a second holder spaced apart from the first holder, wherein the second holder is configured to mount the semiconductor chip on the substrate, and wherein the plurality of units are arranged in a circular configuration;
an induction heating system comprising a first induction coil and a first alternating current supplying unit configured to apply an alternating current to the first induction coil, wherein the induction heating system is configured to heat the junction between the semiconductor chip and the substrate at each of the plurality of units by inducing a magnetic field around the first induction coil; and
a first transferring unit connected to the first induction coil, wherein the first transferring unit is configured to position the first induction coil adjacent each of the plurality of units,
wherein the first transferring unit is configured to move the first induction coil along a circular path and in adjacent spaced apart relationship with the plurality of units, and wherein the induction heating system is configured to sequentially heat the junction between the semiconductor chip and the substrate at each of the plurality of units as the first induction coil is moved along the circular path.

15. The bonding apparatus of claim 14, wherein the induction heating system further comprises a second induction coil spaced apart from the first induction coil, and a second alternating current supplying unit configured to apply an alternating current to the second induction coil.

16. The bonding apparatus of claim 15, further comprising a second transferring unit connected to the second induction coil, wherein the second transferring unit is configured to move the second induction coil along the circular path and in adjacent spaced apart relationship with the plurality of units,
wherein the induction heating system is configured to sequentially heat the junction between the semiconductor chip and the substrate at each of the plurality of units by inducing a magnetic field around the second induction coil as the second induction coil is moved along the circular path, and
wherein the second induction coil is spaced apart from the first induction coil and the plurality of units are positioned therebetween.

17. A method of operating a bonding apparatus, the method comprising:
supporting a first substrate with a first holder;
picking up a first semiconductor chip with a second holder, and then aligning and mounting the first semiconductor chip on the first substrate using the second holder;
positioning, via a first transferring unit, a first induction coil in adjacent spaced apart relationship with the second holder;
applying, via a first alternating current supplying unit, an alternating current to the first induction coil to heat a first junction between the first substrate and the first semiconductor chip by inducing a magnetic field around the first induction coil;
positioning, via the first transferring unit, the first induction coil in adjacent spaced apart relationship with a second substrate and a second semiconductor chip mounted on the second substrate, wherein the second substrate and the second semiconductor chip are adjacent the first substrate and the first semiconductor chip; and
applying, via the first alternating current supplying unit, an alternating current to the first induction coil to heat a second junction between the second substrate and the second semiconductor chip by inducing a magnetic field around the first induction coil.

18. The method of claim 17, further comprising:
simultaneously with applying the alternating current to the first induction coil to heat the first junction between the first substrate and the first semiconductor chip, supporting the second substrate with a third holder that is positioned adjacent the first holder; and
picking up the second semiconductor chip with a fourth holder that is positioned adjacent the second holder, and then aligning and mounting the second semiconductor chip on the second substrate using the fourth holder.

19. The operating method of claim 17, further comprising:
positioning, via a second transferring unit, a second induction coil in adjacent spaced apart relationship with the first holder; and
applying, via a second alternating current supplying unit, an alternating current to the second induction coil to heat the first junction between the first substrate and the first semiconductor chip by inducing a magnetic field around the second induction coil,
wherein applying the first alternating current to the first induction coil to heat the first junction between the first substrate and the first semiconductor chip is performed simultaneously with applying the second alternating current to the second induction coil to heat the first junction between the first substrate and the first semiconductor chip.

20. The method of claim 19, wherein the first induction coil and the second induction coil are spaced apart from each other in a second direction that is transverse to the first direction and the first holder and the second holder are positioned therebetween.
